(19) United States
(12) Patent Application Publication
(10) Pub. No.: US 2006/0011964 A1
(43) Pub. Date: Jan. 19, 2006

(54) Semiconductor device and method for fabricating the same

(75) Inventor: Yoshihiro Satou, Niigata (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/147,382

(22) Filed: Jun. 8, 2005

(30) Foreign Application Priority Data
Jul. 14, 2004 (JP) 2004-207765

(51) Int. Cl. H01L 29/94

(52) U.S. Cl. 257/306

(57) ABSTRACT

In a semiconductor device of the present invention, capacitors are formed on a part of an interlayer dielectric (26) located in a memory cell area, and another interlayer dielectric (39) is formed on a part of still another interlayer dielectric (30) located in a peripheral circuit area AreaB. Furthermore, a dummy electrode is formed at the boundary AreaC between the memory cell area AreaA and the peripheral circuit area AreaB to cover one side of the another interlayer dielectric (30) and the top surface of the interlayer dielectric (26).

### CROSS-REFERENCE TO RELATED APPLICATIONS

This application claims priority under 35 U.S.C. § 119 on Patent Application No. 2004-207765 filed in Japan on Jul. 14, 2004, the entire contents of which are hereby incorporated by reference.

### BACKGROUND OF THE INVENTION

(1) Field of the Invention

The present invention relates to a semiconductor device and a method for fabricating the same, and more particularly relates to a semiconductor device having a DRAM (Dynamic Random Access Memory) and a method for fabricating the same.

(2) Description of Related Art

In recent years, as the degree of integration of semiconductor devices has been increasing, miniaturization of element structures has been advanced. For example, for DRAMs, it has become significant that each memory cell is provided with a capacitor having a large electrostatic capacity per unit area occupied in a DRAM chip to cope with the miniaturization. In order to increase the area over which an upper electrode and a lower electrode of each capacitor are faced to each other, for example, attempts have been made to form a cylindrical electrode as a lower electrode, resulting in the increased surface area of the lower electrode and the increased electrostatic capacity of each capacitor. However, in a DRAM using cylindrical electrode structures for capacitors, a global level difference is produced on the substrate by arraying the capacitors in a memory cell area. This significantly affects lithography after the next process step. To cope with this, a process is typically carried out in which an interlayer dielectric is formed on the capacitors and thereafter the interlayer dielectric is planarized by CMP (Chemical Mechanical Polishing) (see, for example, Japanese Unexamined Patent Publication No. 2002-217388).

A description will be given below of planarization of a known interlayer dielectric formed on capacitors. FIGS. 7A and 7B are cross-sectional views showing process steps in a known method for fabricating a semiconductor device. A memory cell area AreaA in which memory cells are formed is shown at the left side of each of FIGS. 7A and 7B. A peripheral circuit area AreaB in which peripheral circuits are formed is shown at the right side of each of FIGS. 7A and 7B.

According to a known semiconductor device fabricating method, first, in a process step shown in FIG. 7A, an isolation region 102 is formed in a semiconductor substrate 101, and then gate dielectrics 103, gate electrodes 104, an interlayer dielectric 105, contact plugs 106, and metal interconnects 107 are successively formed on the semiconductor substrate 101. Thereafter, a silicon nitride film 108 is formed on the interlayer dielectric 105, and then capacitors 112 composed of lower electrodes 109 each having a circular bottom and a cylindrical side, a capacitor dielectric 110 and an upper electrode 111 are also formed on the interlayer dielectric 105. Subsequently, a 1300-nm-thick silicon oxide film 113 is formed to cover the capacitors 112. A global level difference t arising from the capacitors 112 is produced at a part of the top surface of the silicon oxide film 113 located around the boundary between the memory cell area AreaA and the peripheral circuit area AreaB. This level difference t is approximately equivalent to the height of each capacitor 112 (1000 nm).

Subsequently, in a process step shown in FIG. 7B, the silicon oxide film 113 is polished by CMP to planarize its top surface, and then contact plugs 114 and metal interconnects 115 are formed, thereby completing a semiconductor device including a DRAM.

However, the above-mentioned known semiconductor device fabricating method has caused the following problems.

First, when the silicon oxide film 113 is polished by CMP, the actual amount of the silicon oxide film 113 polished varies ±10% from a desired amount of the silicon oxide film 113 polished (polishing amount variations). Therefore, in order to prevent the silicon oxide film 113 from being excessively removed, the silicon oxide film 113 need be set to become thicker. However, if the silicon oxide film 113 is set to become thicker, this increases variations in the thickness of the actually formed silicon oxide film from the desired thickness thereof (film formation variations) and also increases the amount of the silicon oxide film 113 polished by CMP, resulting in increased polishing amount variations.

### SUMMARY OF THE INVENTION

It is an object of the present invention to reduce film formation variations and polishing amount variations of an interlayer dielectric deposited on capacitors in a semiconductor device including a memory cell area comprising three-dimensional capacitors and a peripheral circuit area.

A semiconductor device of the present invention having a memory cell area and a peripheral circuit area, comprises: a plurality of three-dimensional capacitors formed on a front-end film in the memory cell area and each having a lower electrode, a capacitor dielectric formed on the lower electrode and an upper electrode formed on the capacitor dielectric; a first dielectric formed on the front-end film in the peripheral circuit area; a dummy electrode formed at the boundary between the memory cell area and the peripheral circuit area to cover one side of the first dielectric and the top of the front-end film; and a second dielectric formed over the plurality of capacitors, the first dielectric and the dummy electrode.

With this semiconductor device, since the first dielectric is formed, this reduces the difference in the density of objects formed on the front-end film between the memory cell area and the peripheral circuit area. Therefore, in process steps for fabricating this semiconductor device, a global level difference in the second dielectric can be restrained from being produced at the boundary between the memory cell area and the peripheral circuit area when the second dielectric is deposited. In this way, the second dielectric to be deposited can be made thinner. This can reduce the film formation variations, and the decreased thickness of a part of the second dielectric to be polished can reduce the polishing amount variations.

By the way, process steps for fabricating the semiconductor device of the present invention includes a process step of removing parts of the first dielectric remaining between adjacent ones of the plurality of capacitors before the deposition of the second dielectric. Since in the semiconductor device of the present invention the dummy electrode is formed to cover one side of the first dielectric and the top of the front-end film, the use of the dummy electrode as a mask in this removal process step can prevent a part of the first dielectric located in the peripheral circuit area and the front-end film from being removed. This can prevent a global level difference in the second dielectric from being eventually produced due to the removal of the intentionally formed first dielectric. The “front-end film” means a transistor-level film structure formed under an interconnect layer.

The “three-dimensional” capacitors means that the upper and lower electrodes of the capacitors are not simply formed two-dimensionally but each have unevenness. For example, as described in embodiments of the present invention, a cylindrical lower electrode is formed, and an upper electrode is formed along the uneven shape of the lower electrode.

The dummy electrode may be ring-shaped to surround the sides of the memory cell area, and the peripheral circuit area may surround the sides of the dummy electrode. The “ring shape” may be a circular shape or a polygonal shape as described in the embodiments.

It is preferable that the dummy electrode covers the one side of the first dielectric to reach the upper end of the first dielectric. In this case, the first dielectric can certainly be protected in the process step of removing parts of the first dielectric remaining between adjacent ones of the plurality of capacitors.

The dummy electrode and the lower electrode are preferably obtained by patterning a single film. In this case, the dummy electrode can be formed without increasing the number of process steps as compared with that of known process steps.

The dummy electrode may be a dummy lower electrode, and the device may further comprise a dummy capacitor dielectric formed on the dummy lower electrode; and a dummy upper electrode formed on the dummy capacitor dielectric.

The dummy lower electrode may be electrically isolated from the lower electrode, and the dummy upper electrode may be integral with the upper electrode.

The front-end film may include a semiconductor substrate, and the device further comprise: a plurality of MIS transistors for memory cells formed at the semiconductor substrate in the memory cell area and electrically connected to the associated capacitors; a MIS transistor for a peripheral circuit formed at the semiconductor substrate in the peripheral circuit area; and a third dielectric formed on the semiconductor substrate to cover the plurality of MIS transistors for memory cells and the MIS transistor for a peripheral circuit.

The lower electrode may have substantially a circular bottom and a cylindrical side.

The surfaces of the first dielectric and the second dielectric are preferably planarized. This can result in the further planarized surface of the second dielectric.

A method for fabricating a semiconductor device of the present invention having a memory cell area and a peripheral circuit area comprises the steps of: (a) forming a first dielectric on a front-end film; (b) after the step (a), forming a plurality of recesses in a part of the first dielectric located in the memory cell area and forming a groove in a part of the first dielectric located at the boundary between the memory cell area and the peripheral circuit area to surround the sides of the memory cell area; (c) after the step (b), forming lower electrodes on the entire surfaces of the plurality of recesses and forming a dummy electrode on the entire surface of the groove; (d) after the step (c), removing, in the memory cell area, parts of the first dielectric located between adjacent ones of the plurality of recesses and leaving a part of the first dielectric located in the peripheral circuit area; (e) forming a capacitor dielectric on the lower electrode after the step (d); (f) forming an upper electrode on the capacitor dielectric after the step (e); and (g) forming a second dielectric to cover the upper electrode and the first dielectric after the step (f).

Since in the step (b) the first dielectric is thus left in the peripheral circuit area, this reduces the difference in the density of objects formed on the front-end film between the memory cell area and the peripheral circuit area. Therefore, in the step (g), a global level difference can be restrained from being produced at the boundary between the memory cell area and the peripheral circuit area and in the surface of the second dielectric. In this way, the second dielectric to be deposited can be made thinner. This can reduce the film formation variations, and the decreased thickness of a part of the second dielectric to be polished can reduce the polishing amount variations.

Furthermore, since in the step (c) the surface of a part of the first dielectric located in the peripheral circuit area is covered with the dummy electrode, this can prevent a part of the first dielectric located in the peripheral circuit area from being removed with the removal of parts of the first dielectric located in the memory cell area in the step (d). This can prevent a global level difference from being eventually produced due to the removal of the intentionally formed part of the first dielectric.

The front-end film may include a semiconductor substrate, and the method may further comprise the steps of: (h) forming MIS transistors for memory cells at a part of the semiconductor substrate located in the memory cell area before the step (a); (i) forming a MIS transistor for a peripheral circuit at a part of the semiconductor substrate located in the peripheral circuit area before the step (a); and 0) forming a third dielectric on the semiconductor substrate to cover the MIS transistors for memory cells and the MIS transistor for a peripheral circuit after the steps (h) and (i) and before the step (a), wherein in the step (a), the first dielectric may be formed over the third dielectric.

It is preferable that in the step (d), a resist is formed to cover a part of the first dielectric located in the peripheral circuit area and have an opening on a part of the first dielectric located in the memory cell area and then wet etching is carried out using the resist as a mask. Therefore, a part of the first dielectric located in the peripheral circuit area can certainly be protected.

In the step (d), the edge of the resist is preferably located on the dummy electrode. Therefore, a part of the first dielectric located in the peripheral circuit area can be protected by the resist and the dummy electrode.

The dummy electrode may be a dummy lower electrode. In the step (e), a dummy capacitor dielectric may be formed on the dummy lower electrode, and in the step (f), a dummy upper electrode may be formed on the dummy capacitor dielectric.

### BRIEF DESCRIPTION OF THE DRAWINGS

FIG. 1 is a plan view showing a schematic structure of a semiconductor device according to embodiments of the present invention.

FIGS. 2A through 2E are cross-sectional views showing some of process steps in a method for fabricating a semiconductor device according to a first embodiment of the present invention.

FIGS. 3A through 3D are cross-sectional views showing some of process steps in the method for fabricating a semiconductor device according to the first embodiment of the present invention.

FIGS. 4A through 4C are cross-sectional views showing some of process steps in the method for fabricating a semiconductor device according to the first embodiment of the present invention.

FIG. 5 is a cross-sectional view showing one of process steps in the method for fabricating a semiconductor device according to the first embodiment of the present invention.

FIGS. 6A and 6B are cross-sectional views showing some of process steps in a method for fabricating a semiconductor device according to a second embodiment of the present invention.

FIGS. 7A and 7B are cross-sectional views showing process steps in a known method for fabricating a semiconductor device.

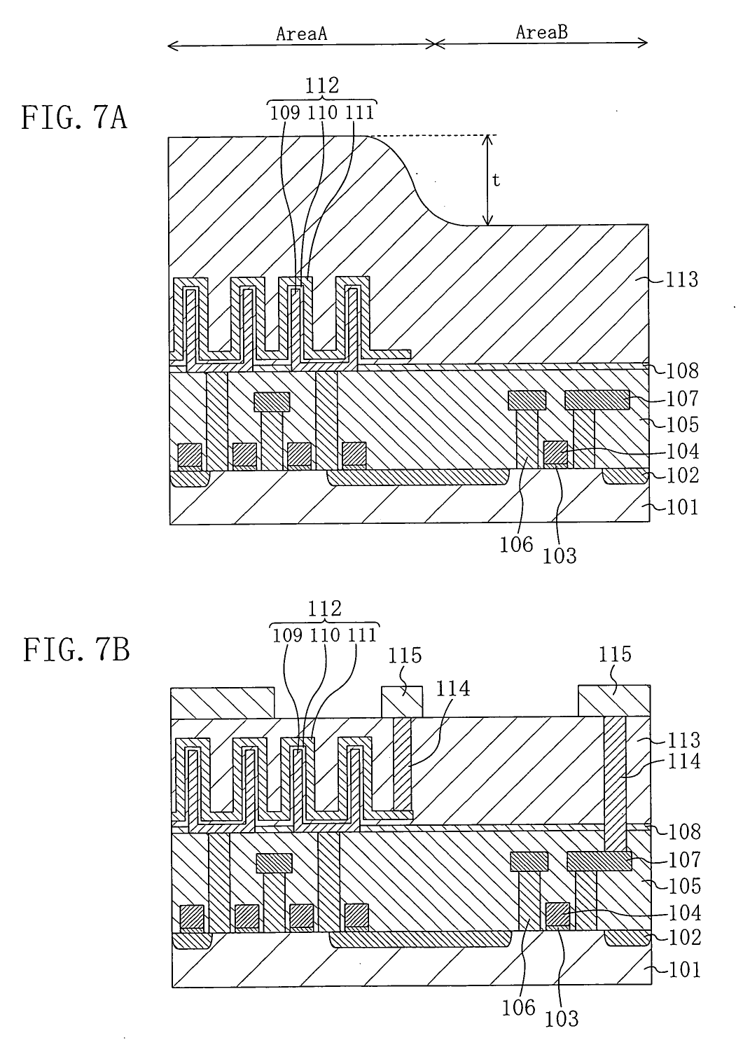

### DETAILED DESCRIPTION OF THE INVENTION

A method for fabricating a semiconductor device according to embodiments of the present invention will be described hereinafter with reference to the drawings.

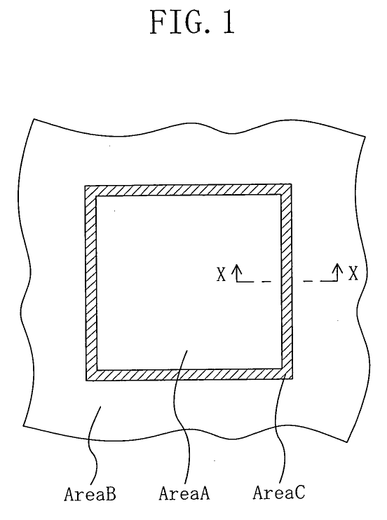

FIG. 1 is a plan view showing a schematic structure of a semiconductor device according to the embodiments of the present invention. The semiconductor device of these embodiments comprises a memory cell area AreaA in which MIS transistors for memory cells are formed, a dummy cell area AreaC in which a ring-shaped dummy capacitor is formed to surround the sides of the memory cell area AreaA, a peripheral circuit area AreaB located on the outside of the dummy cell area AreaC and in which MIS transistors for peripheral circuits are formed. A description will be given with reference to cross-sectional views taken along the line X-X in FIG. 1.

### Embodiment 1

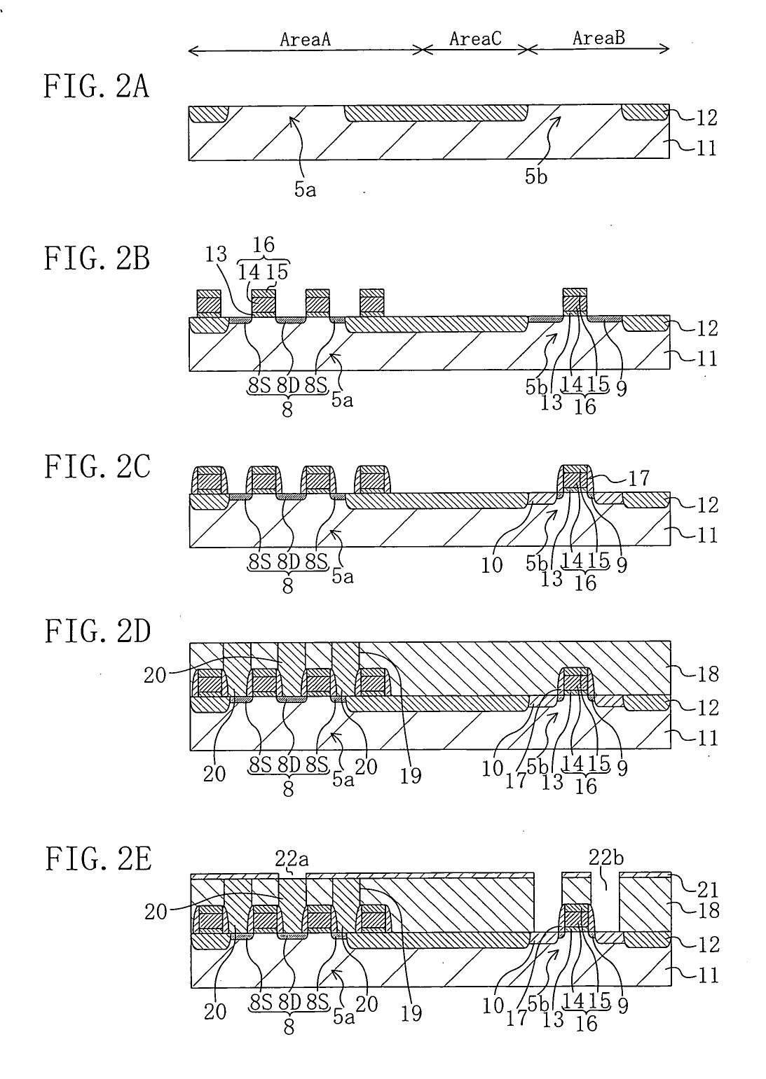

A method for fabricating a semiconductor device according to a first embodiment of the present invention will be described hereinafter with reference to the drawings. FIGS. 2A through 4C and 5 are cross-sectional views showing process steps in the method for fabricating a semiconductor device according to the first embodiment of the present invention.

According to a method for fabricating a semiconductor device of the present invention, first, in a process step shown in FIG. 2A, a shallow trench isolation region 12 is formed in a semiconductor substrate 11 to surround respective active regions 5a and 5b of a memory cell area AreaA and a peripheral circuit area AreaB. Subsequently, desired ion implantation is carried out, thereby forming well diffusion layers and threshold-voltage-controlling impurity layers (both not shown) in the memory cell area AreaA and the peripheral circuit area AreaB. In this case, a p-type well is formed in the memory cell area AreaA, and a p-type well and an n-type well are formed in the peripheral circuit area AreaB to form NMIS and PMIS transistors, respectively. In this relation, for simplification, only the NMIS transistor is shown in the peripheral circuit area AreaB.

Next, in a process step shown in FIG. 2B, a 6- through 7-nm-thick gate dielectric 13 made of a silicon oxide film or a silicon oxynitride film is formed on the active regions 5a and 5b of the semiconductor substrate 11 surrounded by the isolation region 12. Thereafter, a 70-nm-thick phosphorus-doped polysilicon film (not shown) is formed on the gate dielectric 13 by CVD, and a 50-nm-thick tungsten nitride (WN) film (not shown) and a 100-nm-thick tungsten (W) film (not shown) are successively formed on the polysilicon film by sputtering. Then, a 150-nm-thick silicon nitride film (not shown) is further formed on the W film by CVD. Subsequently, the polysilicon film, the WN film, the W film, and the silicon nitride film are patterned to form gate electrode sections 16, each of which is composed of a gate electrode 14 made of a multilayer film of the polysilicon film, the WN film and the W film and an on-gate dielectric 15 made of a silicon nitride film. Thereafter, a resist film (not shown) is formed to cover the entire surface of the peripheral circuit area AreaB, and then ions of n-type impurities, such as phosphorus (P), are implanted into the semiconductor substrate 11 using the resist film and the gate electrode sections 16 located in the memory cell area AreaA as masks. In this way, n-type source/drain regions 8 are formed in parts of the active region 5a of the memory cell area AreaA located to the sides of the gate electrode sections 16. Subsequently, the resist film is removed. Next, a resist film (not shown) is formed to cover the entire surface of the memory cell area AreaA. Thus, ions of n-type impurities, such as phosphorus, are implanted into the semiconductor substrate 11 using the resist film and the gate electrode section 16 located in the peripheral circuit area AreaB as masks. In this way, n-type lightly-doped source/drain regions 9 are formed in parts of the active region 5b of the peripheral circuit area AreaB located to the sides of the gate electrode section 16.

Next, in a process step shown in FIG. 2C, the resist film is removed, and then a 50-nm-thick silicon nitride film (not shown) is entirely formed in the semiconductor substrate 11 region by CVD. The silicon nitride film is subjected to anisotropic dry etching, thereby forming sidewalls 17 on the sides of the gate electrode sections 16. Thereafter, a resist film (not shown) is formed to cover the entire surface of the memory cell area AreaA, and ions of n-type impurities, such as arsenic (As), are implanted into the semiconductor substrate 11 using the resist film and the gate electrode section 16 and the sidewall 17 both located in the peripheral circuit area AreaB as masks. In this way, n-type heavily-doped source/drain regions 10 are formed in parts of the active region 5b of the peripheral circuit area AreaB located to the sides of the sidewall 17.

Next, in a process step shown in FIG. 2D, the resist film (not shown) is removed, and subsequently an 800-nm-thick interlayer dielectric 18 of a silicon oxide film is deposited by CVD and then polished by CMP to planarize its surface. Thereafter, a resist film (not shown) is formed on the interlayer dielectric 18 to have openings on the n-type source/drain regions 8 in the memory cell area AreaA. The interlayer dielectric 18 is dry-etched using the resist film as a mask, thereby forming contact holes 19 passing through the interlayer dielectric 18 and reaching the n-type source/drain regions 8. Thereafter, a polysilicon film containing n-type impurities, such as phosphorus (P), is deposited on the interlayer dielectric 18 by CVD to fill the contact holes 19, and then the polysilicon film is polished by CMP so as to be left only inside the contact holes 19. In this way, contact plugs 20 are formed.

Next, in a process step shown in FIG. 2E, a 200-nm-thick protective dielectric 21 of a silicon oxide film is formed on the interlayer dielectric 18, and then heat treatment is performed at a temperature of approximately 800° C. This heat treatment allows n-type impurities contained in polysilicon constituting the contact plugs 20 to diffuse from the bottoms of the contact holes 19 into the n-type source/drain regions 8. This reduces the resistances of the n-type source/drain regions 8. Subsequently, a resist film (not shown) is formed on the protective dielectric 21 to have an opening on a drain region 8D of the MIS transistor for a memory cell. Then, the protective dielectric 21 is dry-etched using the resist film as a mask, thereby forming an opening 22a reaching the contact plug 20 connected to the drain region 8D of the MIS transistor for a memory cell. Subsequently, the resist film is removed, and a resist film (not shown) is formed on the protective dielectric 21 to have openings on the n-type heavily-doped source/drain regions 10 of the MIS transistor in the peripheral circuit area AreaB. Thereafter, the protective dielectric 21 is dry-etched using the resist film as a mask, thereby forming contact holes 22b passing through the protective dielectric 21 and the interlayer dielectric 18 and reaching the n-type heavily-doped source/drain regions 10.

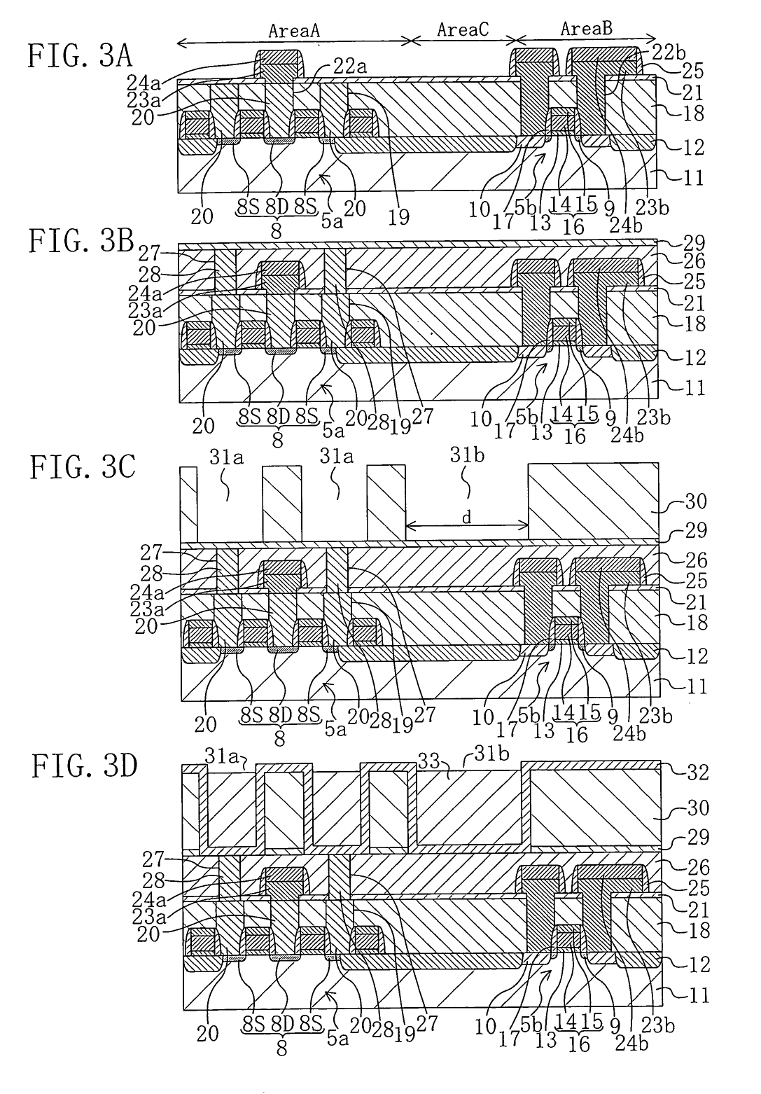

Next, in a process step shown in FIG. 3A, the resist film is removed, and then a titanium (Ti) film (not shown) is deposited on the protective dielectric 21 by CVD. In this case, in the memory cell area AreaA, the Ti film fills the opening 22a and is deposited on the protective dielectric 21 to have a thickness of 5 nm, while, in the peripheral circuit area AreaB, it fills the contact holes 22b and is also deposited on the protective dielectric 21 to have a thickness of 5 nm. Next, a 10-nm-thick TiN film (not shown) is deposited on the Ti film by CVD. Furthermore, a 150-nm-thick W film (not shown) and a 200-nm-thick silicon nitride film (not shown) are deposited on the TiN film by CVD. Then, a resist film (not shown) is formed on the silicon nitride film, and the silicon nitride film, the W film, the TiN film, and the Ti film are patterned using the resist film as a mask. In this way, a metal interconnect 23a of the W film, the TiN film and the Ti film and an on-interconnect dielectric 24a of the silicon nitride film are formed in the memory cell area AreaA. The metal interconnect 23a is connected to the contact plug 20 located on the drain region 8D and thus becomes a bit line. On the other hand, in the peripheral circuit area AreaB, metal interconnects 23b of the W film, the TiN film and Ti film filling the contact holes 22b and extending on the protective dielectric 21 and on-interconnect dielectrics 24b of the silicon nitride film are formed. The W film contained in the metal interconnects 23b comes into contact with the n-type heavily-doped source/drain regions 10 on the bottom of the contact holes 22b. Thereafter, the resist film is removed, and a silicon nitride film (not shown) is entirely formed in a substrate region by CVD. Then, the silicon nitride film is subjected to anisotropic dry etching, thereby forming sidewalls 25 on the sides of the metal interconnects 23a and 23b and the on-interconnect dielectric 24a and 24b.

Next, in a process step shown in FIG. 3B, an 800-nm-thick interlayer dielectric 26 of a silicon oxide film is entirely formed in the substrate region by CVD and then polished by CMP to planarize its surface. Thereafter, a resist film (not shown) is formed on the interlayer dielectric 26 to have openings on the contact plugs 20 connected to source regions 8S in the memory cell area AreaA. The interlayer dielectric 26 is dry-etched using the resist film as a mask, thereby forming contact holes 27 passing through the interlayer dielectric 26 and reaching the associated contact plugs 20. Thereafter, the resist film is removed, and then a polysilicon film (not shown) containing n-type impurities is formed by CVD to fill the contact holes 27 and extend on the interlayer dielectric 26. Subsequently, a part of the polysilicon film extending on the interlayer dielectric 26 is removed by CMP or an etch-back process to form contact plugs 28 filling the contact holes 27. Then, a 100-nm-thick protective dielectric 29 of a silicon nitride film is deposited on the interlayer dielectric 26.

Next, in a process step shown in FIG. 3C, an interlayer dielectric 30 of a silicon oxide film is formed on the protective dielectric 29 by CVD. Thereafter, a resist film (not shown) is formed on the interlayer dielectric 30 to have openings in the memory cell area AreaA and the dummy cell area AreaC. In the memory cell area AreaA, the resist film has a plurality of circular openings formed at predetermined intervals. In the dummy cell area AreaC, the resist film has a ring-shaped opening formed to two-dimensionally surround the sides of the memory cell area AreaA. Subsequently, the interlayer dielectric 30 is dry-etched using the resist film as a mask, thereby forming recesses 31a for capacitor formation at predetermined intervals in the memory cell area AreaA. At the same time, a groove 31b is formed in the dummy cell area AreaC to two-dimensionally surround the sides of the memory cell area AreaA. When the interlayer dielectric 30 is dry-etched as described above, the protective dielectric 29 serves as an etching stopper. Therefore, the interlayer dielectric 26 that is an underlayer of the protective dielectric 29 is not etched. In the dummy cell area AreaC, the width of the groove 31b is preferably about 1 μm or more, which permits, in a later process step, resist patterning for leaving only a part of a resist in the groove 31b and removing the other part thereof.

Next, in a process step shown in FIG. 3D, the resist film is removed, and then parts of the protective dielectric 29 exposed at the recesses 31 and the groove 31b are removed by etching. In this case, the silicon nitride film (protective dielectric) 29 is etched back by dry etching on conditions that the protective dielectric 29 is given a higher etching selectivity than the silicon oxide film (interlayer dielectric) 30, thereby removing parts of the protective dielectric 29 in the recesses 31a and the groove 31b. The interlayer dielectric 30 is used as a mask in this etching. Therefore, parts of the protective dielectric 29 located under the interlayer dielectric 30 are not removed. Subsequently, a 50-nm-thick lower-electrode-forming film 32 of a phosphorus-doped amorphous silicon film is entirely formed in the substrate region by CVD to cover the bottoms and sides of the recesses 31a and the groove 31b.

Thereafter, a posi resist film (not shown) is applied to the entire substrate region to fill the recesses 31a and the groove 31b all covered with the lower-electrode-forming film 32 and extend on the interlayer dielectric 30 with the lower-electrode-forming film 32 interposed between the interlayer dielectric 30 and the posi resist film. Then, the entire surface of the posi resist film is exposed to light to the extent that light reaches a whole part of the posi resist film located above the interlayer dielectric 30 but does not reach parts of the posi resist film filling the recesses 31a and the groove 31b. Thereafter, the posi resist film is developed. In this way, the posi resist film is selectively removed to the depth to which it is exposed to light, i.e., the part of the posi resist film located above the interlayer dielectric 30 is removed, and posi resist films 33 that are unexposed parts of the posi resist film are left in the recesses 31a and the groove 31b. Instead of selective exposure of the posi resist film to light as described above, a resist film may be formed over the entire substrate region and then etched back to leave the resist films 33 only in the recesses 31a and the groove 31b.

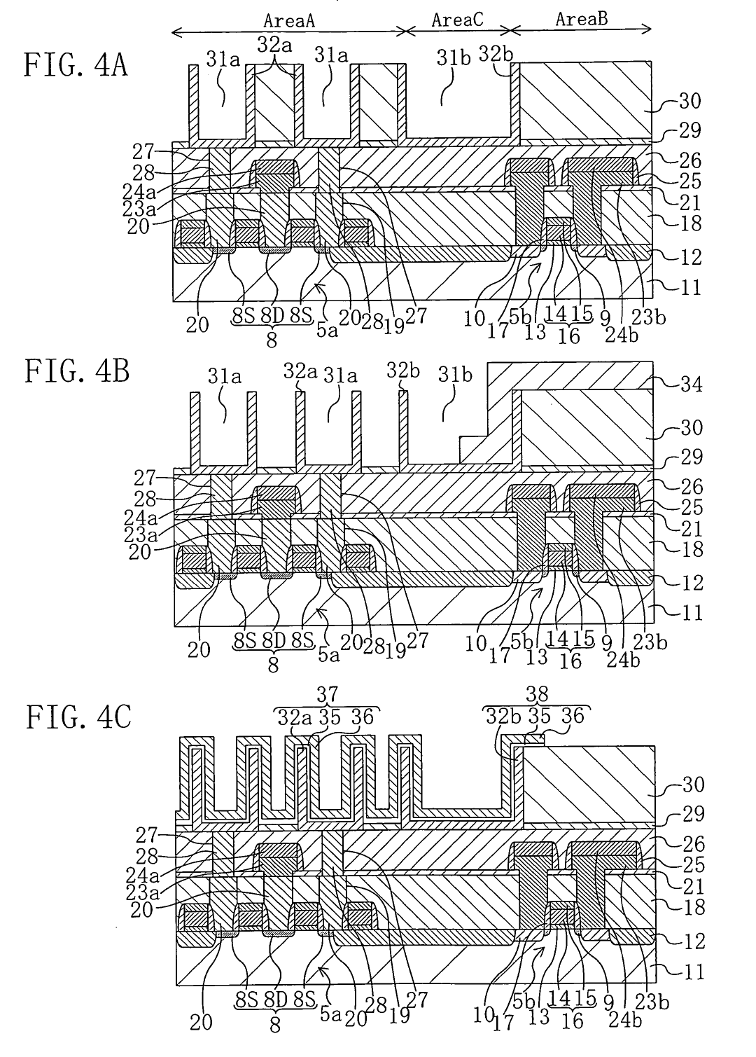

Next, in a process step shown in FIG. 4A, the lower-electrode-forming film 32 is dry-etched using the resist film 33 (shown in FIG. 3D) as a mask, thereby removing parts of the lower-electrode-forming film 32 located on the interlayer dielectric 30 and leaving, in the recesses 31a and the groove 31b, the other parts of the lower-electrode-forming film 32 that will serve as lower electrodes 32a and a dummy lower electrode 32b. Thereafter, the resist film 33 is removed. The lower electrodes 32a are electrically connected through the contact plugs 20 and 27 to the source regions 8S of the MIS transistor in the memory cell area AreaA. On the other hand, the dummy lower electrode 32b is formed on the interlayer dielectric 26 and not electrically connected to the semiconductor substrate 11, thereby taking on a floating state.

Next, in a process step shown in FIG. 4B, a resist film (not shown) is entirely applied to the substrate region, and the resist film is exposed to light and developed. In this way, a resist film 34 is formed to cover a region including part of the interlayer dielectric 30 located in the peripheral circuit area AreaB and a part of the dummy lower electrode 32b in the dummy cell area AreaC and expose another part of the dummy lower electrode 32b in the dummy cell area AreaC and parts of the interlayer dielectric 30 in the memory cell area AreaA. In other words, a resist film 34 is formed by patterning the resist film to have an edge located on the dummy lower electrode 32b and in the groove 31b. Wet etching using an etchant such as HF is carried out using the resist film 34 as a mask to selectively remove the exposed interlayer dielectric 30 in the memory cell area AreaA. In this way, the lower electrodes 32a are formed to each have a circular bottom and a cylindrical side. The protective dielectric 29 located under the interlayer dielectric 30 serves as an etching stopper in this etching.

Next, in a process step shown in FIG. 4C, a dielectric (not shown) and an upper-electrode-forming film (not shown) are entirely formed in the substrate region, and then the dielectric and the upper-electrode-forming film are etched using, as a mask, a resist film covering the memory cell area AreaA and the dummy cell area AreaC. In this way, a capacitor dielectric 35 is formed to cover the entire surfaces of the lower electrodes 32a and the dummy lower electrode 32b, and an upper electrode 36 is formed to cover the entire surface of the capacitor dielectric 35. Thus, capacitors 37 for memory cells, which are each composed of a lower electrode 32a, a part of the capacitor dielectric 35 and a part of the upper electrode 36, and a dummy capacitor 38, which is composed of the dummy lower electrode 32b, a part of the capacitor dielectric 35 and a part of the upper electrode 36, are formed.

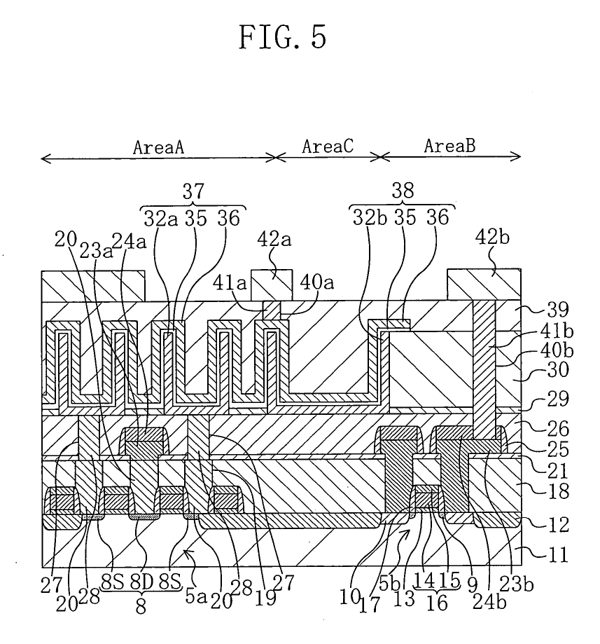

Next, in a process step shown in FIG. 5, a 300-nm-thick interlayer dielectric 39 of a silicon oxide film is formed by CVD to entirely cover the upper electrode 36 and a part of the interlayer dielectric 30 located in the peripheral circuit area AreaB. Thereafter, the surface of the interlayer dielectric 39 is planarized by CMP. Subsequently, a contact hole 40a is formed in the memory cell area AreaA to pass through the interlayer dielectric 39 and reach the upper electrode 36, and a contact hole 40b is formed in the peripheral circuit area AreaB to pass through the interlayer dielectrics 39 and 30, the protective dielectric 29, the interlayer dielectric 26, and the on-interconnect dielectric 24b and reach the metal interconnect 23b. Then, the contact holes 40a and 40b are filled with a metal film (not shown), such as a W film, and then an unnecessary part of the metal film located on the interlayer dielectric 39 is removed by CMP to form contact plugs 41a and 41b. Subsequently, metal interconnects 42a and 42b are formed on the interlayer dielectric 39 so as to be connected to the contact plugs 41a and 41b. The above-mentioned process steps permit the formation of a semiconductor device having a DRAM as shown in FIG. 5. After these process steps, passivation films are further deposited on a multilayer interconnect and the uppermost interconnect, respectively, although not shown.

In this embodiment, in the process step shown in FIG. 4B, parts of the interlayer dielectric 30 remaining between adjacent ones of the plurality of lower electrodes 32a are removed in the memory cell area AreaA, and the interlayer dielectric 30 is left in the peripheral circuit area AreaB. Since the interlayer dielectric 30 is formed in the peripheral circuit area AreaB, the distances between adjacent ones of the recesses and groove formed on the interlayer dielectric 26 can be made small. Therefore, a global level difference can be restrained from being produced at the boundary between the memory cell area AreaA and the peripheral circuit area AreaB when the interlayer dielectric 39 is deposited on the capacitors 37 and the interlayer dielectric 30 in the process step shown in FIG. 5. In this way, the interlayer dielectric 39 to be deposited can be made thinner. This can reduce the film formation variations, and the thickness of a part of the interlayer dielectric 39 to be polished can be decreased to reduce the polishing amount variations.

Furthermore, in this embodiment, the dummy lower electrode 32b is formed, and etching is performed with the edge of the patterned resist film 34 formed on the dummy lower electrode 32b in the process step shown in FIG. 4B. If the edge of the patterned resist film 34 is located on the interlayer dielectric 26 or 30 or the protective dielectric 29 without forming the dummy lower electrode 32b, etching will proceed vertically or horizontally so that the interlayer dielectric 26 or 30 will be removed, leading to a level difference. Since in this embodiment the dummy lower electrode 32b is formed, this can prevent the level difference from being produced.

### Embodiment 2

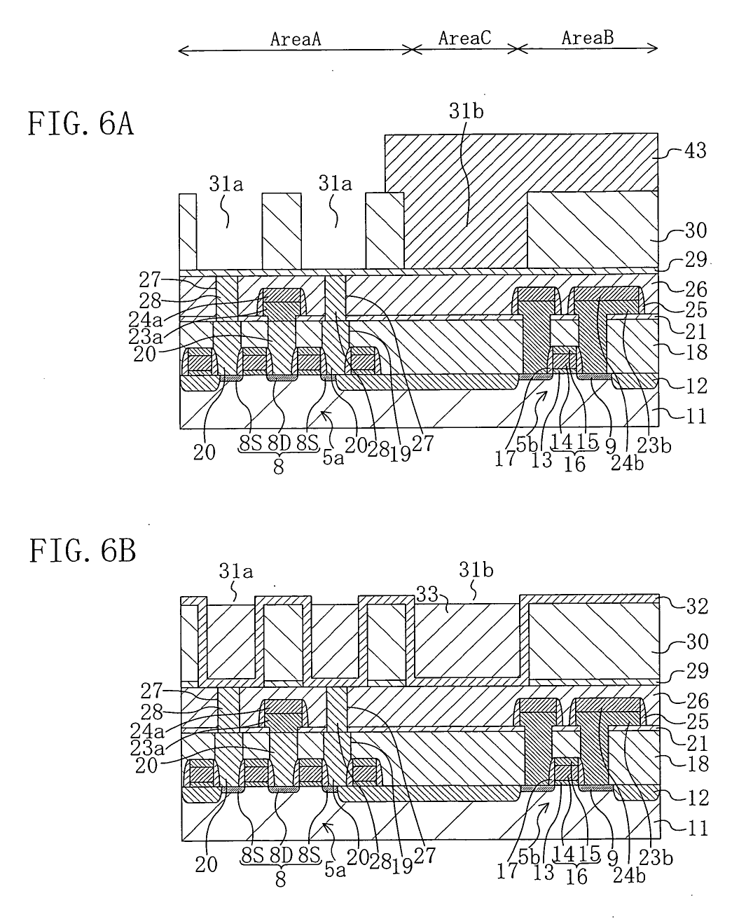

A method for fabricating a semiconductor device according to a second embodiment of the present invention will be described hereinafter with reference to the drawings. FIGS. 6A and 6B are cross-sectional views showing process steps in the method for fabricating a semiconductor device according to the second embodiment of the present invention. A process step shown in FIG. 6A is a process step to be added after the process step of the first embodiment shown in FIG. 3C. A process step shown in FIG. 6B corresponds to the process step of the first embodiment shown in FIG. 3D. Process steps for fabricating a semiconductor device of this embodiment are identical with those of the first embodiment except for the process steps shown in FIGS. 6A and 6B.

In the semiconductor device fabricating method of this embodiment, first, the process steps of the first embodiment are carried out until the process step shown in FIG. 3C has finished. Thereafter, in the process step shown in FIG. 6A, a resist film 43 is entirely formed in a substrate region to cover the dummy cell area AreaC and the peripheral circuit area AreaB and have an opening in the memory cell area AreaA. Thus, in the dummy cell area AreaC, a part of the protective dielectric 29 serving as the bottom of the groove 31b is covered with the resist film 43, while, in the memory cell area AreaA, the surfaces of parts of the protective dielectric 29 serving as the bottoms of the recesses 31a are exposed.

Subsequently, etching is performed using, as masks, the resist film 43 and parts of the interlayer dielectric 30 located in the memory cell area AreaA, thereby removing parts of the protective dielectric 29 exposed at the bottoms of the recesses 31a in the memory cell area AreaA to expose the contact plugs 28. In this case, dry etching is performed on conditions providing a high selectivity of the silicon nitride film that is a material of the protective dielectric 29 to the silicon oxide film that is a material of the interlayer dielectric 30. Then, the resist film 43 is removed.

Next, in the process step shown in FIG. 6B, a 50-nm-thick lower-electrode-forming film 32 of a phosphorus-doped amorphous silicon film is entirely formed in the substrate region to cover the bottoms and sides of the recesses 31a and the groove 31b. Thereafter, a posi resist film (not shown) is applied to the entire substrate region with the lower-electrode-forming film 32 interposed between the bottoms and sides of the recesses 31a and the groove 31b and the posi resist film to fill the recesses 31a and the groove 31b and extend on the interlayer dielectric 30. Then, the entire surface of the posi resist film is exposed to light to the extent that light entirely reaches a part of the posi resist film located above the interlayer dielectric 30 but does not reach parts of the posi resist film filling the recesses 31a and the groove 31b. Thereafter, the posi resist film is developed. In this way, the posi resist film is selectively removed to the depth to which it is exposed to light, i.e., the part of the posi resist film located above the interlayer dielectric 30 is removed, and posi resist films 33 that are unexposed parts of the posi resist film are left in the recesses 31a and the groove 31b. Thereafter, a semiconductor device having a DRAM is completed in accordance with the same process steps as those of the first embodiment shown in FIGS. 4A through 4C and 5.

In this embodiment, like the first embodiment, a global level difference can be restrained from being produced at the boundary between the memory cell area AreaA and the peripheral circuit area AreaB when the interlayer dielectric 39 is deposited. This can reduce the thickness of the interlayer dielectric 39 to be deposited. Therefore, the film formation variations can be reduced. In addition, since a part of the interlayer dielectric 39 to be polished becomes thin, this can reduce the polishing amount variations. Furthermore, like the first embodiment, the level difference can be reduced also by forming the dummy-lower electrode 32b.

### Other Embodiments

In the first and second embodiments, a description was given of the case where a dummy capacitor 38 is formed at the boundary between the memory cell area AreaA and the peripheral circuit area AreaB. However, in the present invention, only the dummy lower electrode 32b may be formed in the dummy capacitor 38. In this case, the capacitor dielectric 35 and the upper electrode 36 may be formed only in the memory cell area AreaA in the process step shown in FIG. 4C. This can also prevent the interlayer dielectric 30 from being removed during the etching in the process step shown in FIG. 4B.

What is claimed is:

1. A semiconductor device having a memory cell area and a peripheral circuit area, the semiconductor device comprising:
a plurality of three-dimensional capacitors formed on a front-end film in the memory cell area and each having a lower electrode, a capacitor dielectric formed on the lower electrode and an upper electrode formed on the capacitor dielectric;
a first dielectric formed on the front-end film in the peripheral circuit area;
a dummy electrode formed at the boundary between the memory cell area and the peripheral circuit area to cover one side of the first dielectric and the top of the front-end film; and
a second dielectric formed over the plurality of capacitors, the first dielectric and the dummy electrode.

2. The device of claim 1, wherein
the dummy electrode is ring-shaped to surround the sides of the memory cell area, and the peripheral circuit area surrounds the sides of the dummy electrode.

3. The device of claim 1, wherein
the dummy electrode covers the one side of the first dielectric to reach the upper end of the first dielectric.

4. The device of claim 1, wherein
the dummy electrode and the lower electrode are obtained by patterning a single film.

5. The device of claim 1, wherein
the dummy electrode is a dummy lower electrode, and
the device further comprises a dummy capacitor dielectric formed on the dummy lower electrode; and a dummy upper electrode formed on the dummy capacitor dielectric.

6. The device of claim 5, wherein
the dummy lower electrode is electrically isolated from the lower electrode, and
the dummy upper electrode is integral with the upper electrode.

7. The device of claim 1, wherein
the front-end film includes a semiconductor substrate, and
the device further comprises:
a plurality of MIS transistors for memory cells formed at the semiconductor substrate in the memory cell area and electrically connected to the associated capacitors;
a MIS transistor for a peripheral circuit formed at the semiconductor substrate in the peripheral circuit area; and
a third dielectric formed on the semiconductor substrate to cover the plurality of MIS transistors for memory cells and the MIS transistor for a peripheral circuit.

8. The device of claim 1, wherein
the lower electrode has substantially a circular bottom and a cylindrical side.

9. The device of claim 1, wherein
the surfaces of the first dielectric and the second dielectric are planarized.

10. A method for fabricating a semiconductor device having a memory cell area and a peripheral circuit area, said method comprising the steps of:
(a) forming a first dielectric on a front-end film;
(b) after the step (a), forming a plurality of recesses in a part of the first dielectric located in the memory cell area and forming a groove in a part of the first dielectric located at the boundary between the memory cell area and the peripheral circuit area to surround the sides of the memory cell area;
(c) after the step (b), forming lower electrodes on the entire surfaces of the plurality of recesses and forming a dummy electrode on the entire surface of the groove;
(d) after the step (c), removing, in the memory cell area, parts of the first dielectric located between adjacent ones of the plurality of recesses and leaving a part of the first dielectric located in the peripheral circuit area;
(e) forming a capacitor dielectric on the lower electrode after the step (d);
(f) forming an upper electrode on the capacitor dielectric after the step (e); and
(g) forming a second dielectric to cover the upper electrode and the first dielectric after the step (f).

11. The method of claim 10, wherein the front-end film includes a semiconductor substrate, and the method further comprises the steps of:
(h) forming MIS transistors for memory cells at a part of the semiconductor substrate located in the memory cell area before the step (a);
(i) forming a MIS transistor for a peripheral circuit at a part of the semiconductor substrate located in the peripheral circuit area before the step (a); and
(j) forming a third dielectric on the semiconductor substrate to cover the MIS transistors for memory cells and the MIS transistor for a peripheral circuit after the steps (h) and (i) and before the step (a),
wherein in the step (a), the first dielectric is formed over the third dielectric.

12. The method of claim 10, wherein
in the step (d), a resist is formed to cover a part of the first dielectric located in the peripheral circuit area and have an opening on a part of the first dielectric located in the memory cell area, and then wet etching is carried out using the resist as a mask.

13. The method of claim 12, wherein
in the step (d), the edge of the resist is located on the dummy electrode.

14. The method of claim 10, wherein
the dummy electrode is a dummy lower electrode,
in the step (e), a dummy capacitor dielectric is formed on the dummy lower electrode, and
in the step (f), a dummy upper electrode is formed on the dummy capacitor dielectric.
